(19) United States
(12) Patent Application Publication
(10) Pub. No.: US 2026/0133249 A1
(43) Pub. Date: May 14, 2026

(54) DELAY LINE CIRCUIT FOR MEASURING PROPAGATION DELAY THROUGH A CIRCUIT

(71) Applicant: Microsemi SOC Corp., Chandler, AZ (US)

(72) Inventor: Aryan Saed, Maple Ridge (CA)

(73) Assignee: Microsemi SOC Corp., Chandler, AZ (US)

(21) Appl. No.: 19/025,145

(22) Filed: Jan. 16, 2025

Related U.S. Application Data
(60) Provisional application No. 63/719,990, filed on Nov. 13, 2024.

(51) Int. Cl. G01R 31/317; H03K 5/00; H03K 5/133; H03K 5/14

(52) U.S. Cl. CPC G01R 31/31725; H03K 5/133; H03K 5/14; H03K 2005/00013

(57) ABSTRACT

A system and method for the identification of system jitter in a circuit are provided. The apparatus may include a delay line circuit including a plurality of combinatorial logic circuits arranged sequentially including a first combinatorial logic circuit and a second combinatorial logic circuit having a plurality of inputs and outputs, a pulse generation circuit to output a generated pulse to a first input of the first combinatorial logic circuit, capture circuit to capture a binary state of at least one of the plurality of outputs. The first and the second combinatorial logic circuits may have a logic propagation path from a first input to a first output. The logic propagation path may have a logic propagation delay between the input pulse and the output pulse determined by a logic value applied to a second input.

### PRIORITY

This application claims priority to U.S. Provisional Patent Application No. 63/719,990 filed Nov. 13, 2024, the contents of which are hereby incorporated in their entirety.

### TECHNICAL FIELD

The present disclosure relates to identification of system jitter in a circuit, such as an Application Specific Integrated Circuit (ASIC) or Field Programmable Gate Array (FPGA).

### BACKGROUND

During operation of an Application Specific Integrated Circuit (ASIC), the currents drawn by analog and digital circuits in the ASIC may cause drops and fluctuations in the supply voltage inside the ASIC. These voltage fluctuations cause dynamic variations in the propagation delay through digital circuits which in turn cause timing jitter in logic signals and clock signals in the ASIC. During the design phase of an ASIC, statistics of these signal fluctuations may be considered, so that the digital and analog circuits operate correctly despite Power Delivery Network (PDN) oscillation and ensuing Total System Jitter (TSJ). Specifically, PDN and TSJ may be factors in the Static Timing Analysis (STA) timing budget that is used during synthesis, placement, and routing phases of the design work.

The PDN of an ASIC is an electrical circuit comprised of load and source impedances, various parasitic impedances and decoupling impedances distributed throughout the ASIC. These impedances may further electrically interact with impedances outside the ASIC, such as the impedances of decoupling and stabilizing capacitors on the board, inductances of bond wires, and impedances of control loops in the power regulators that are part of the Power Supply System (PSS) for the ASIC.

PDN noise inside an ASIC may be determined by supply noise from outside the ASIC, plus internal crosstalk between signal traces and power supply traces, and the effects of dynamic loading of the supply, typically caused by circuit duty cycling and clock edge currents. The amount of PDN noise, and thus the amount of TSJ considered during the circuit design phase of an ASIC, may place limits on the depth and complexity of logic paths that may be implemented in an ASIC. Digital signals meet set-up and hold-times to reliably propagate through logic paths and digital register stages. PDN noise and other variations such as process, voltage level, and temperature, may determine design factors such as maximum clock rate for the intended digital circuits and maximum logic depths between register stages.

A Field Programmable Gate Array (FPGA) is a type of ASIC with programmable logic functions. The programmable fabric circuitry inside the FPGA implements digital logic functions as designed and programmed by a user of the FPGA. FPGA design tools that program digital logic functions inside the FPGA also consider TSJ due to PDN as part of STA: driving, routing, buffering, and loading of digital nets take operating voltage levels, clock jitter, and PDN noise into account. PDN noise may limit the depth and complexity of logic functions that can be programmed in an FPGA. During the design phase, a user generally takes these limits into account when ascertaining that the design on the intended FPGA can achieve the desired system level metrics, such as input and output data rates and the amount of data processing, signal processing and other mathematical operations.

### SUMMARY OF THE INVENTION

Aspects provide systems and methods for the identification of system jitter in a circuit, such as an Application Specific Integrated Circuit (ASIC) or Field Programmable Gate Array (FPGA). Examples of the present disclosure may include an apparatus. The apparatus may include a delay line circuit including a plurality of combinatorial logic circuits arranged sequentially. The plurality of combinatorial logic circuits may include a first combinatorial logic circuit and a second combinatorial logic circuit. Each of the first and the second combinatorial logic circuits may have a plurality of inputs and a plurality of outputs.

The apparatus may include a pulse generation circuit to output a generated pulse to a first input of the first combinatorial logic circuit of the delay line circuit. The apparatus may also include a capture circuit to capture a binary state of at least one of the plurality of outputs of at least one of the plurality of combinatorial logic circuits. Each of the first and the second combinatorial logic circuits may have a logic propagation path from a first input of the plurality of inputs to a first output of the plurality of outputs. The first input of the plurality of inputs may be to receive an input pulse and the first output of the plurality of outputs to output an output pulse. The logic propagation path may have a logic propagation delay between the input pulse and the output pulse. The logic propagation delay may be determined by a logic value applied to a second input of the plurality of inputs. The first output of the first combinatorial logic circuit may be communicatively coupled to a first input of the second combinatorial logic circuit to propagate the generated pulse through the delay line circuit.

In combination with any of the above examples, the plurality of combinatorial logic circuits may include a plurality of logic look up tables. the plurality of inputs may be inputs of the plurality of logic look up tables, and the plurality of outputs may be outputs of the plurality of logic look up tables.

In combination with any of the above examples, the logic look up table may be a programmable logic function in a programmable fabric of a field programmable gate array.

In combination with any of the above examples, the plurality of combinatorial logic circuits may have a bypass control input to accept the input pulse at a bypass input. The pulse generation circuit may be to output the generated pulse to the bypass input of one or more of the plurality of combinatorial logic circuits to bypass the one or more combinatorial logic circuits in the delay line circuit.

In combination with any of the above examples, a launch of the generated pulse may be triggered by a first clock signal and a capture of the binary state is triggered by a second clock signal.

In combination with any of the above examples, the first clock signal may have a phase offset relative to the second clock signal.

In combination with any of the above examples, the plurality of combinatorial logic circuits may include a plurality of logic look up tables, the bypass input may be a first input of each of the plurality of logic look up tables, the bypass control input may be a second input of each of the plurality of logic look up tables, and the output may be an output of each of the plurality of logic look up tables.

In combination with any of the above examples, the capture circuit may be to capture an aggregate state of the plurality of combinatorial logic circuits by capturing the binary state of at least one of the plurality of outputs of each of the first and the second combinatorial logic circuits. The capture circuit may also be to calculate from the aggregate state of the plurality of combinatorial logic circuits an aggregate propagation delay through the delay line circuit.

In combination with any of the above examples, the apparatus may also include a control circuit. The control circuit may be to trigger, at a first time interval, a launch of the generated pulse. The control circuit may also be to trigger, at a second time interval, a capture of the binary state of at least one of the plurality of outputs of the first and the second combinatorial logic circuits.

In combination with any of the above examples, the apparatus may also include a data processing and storage circuit. The data processing and storage circuit may be to store the captures of the binary states of at least one of the plurality of outputs of each of the first and the second combinatorial logic circuits. The data processing and storage circuit may also be to generate a time series of a plurality of aggregate propagation delays.

In combination with any of the above examples, the data processing and storage circuit may be to calculate one or more resonant frequencies based on the time series.

In combination with any of the above examples, the data processing and storage circuit may be to determine, based on the time series, a maximum aggregate propagation delay or a minimum aggregate propagation delay.

In combination with any of the above examples, the apparatus may include a programmable fabric in a field programmable gate array to perform a function programmed by a user. The programmable fabric may be to draw an electrical current from a power delivery network of the field programmable gate array, the power delivery network to supply power to the delay line circuit. The aggregate propagation delay may indicate fluctuations in a voltage supplied by the power delivery network.

In combination with any of the above examples, the data processing and storage circuit may be to relate a start time of the function with a time in the time series.

Alone or in combination with any of the above examples, examples of the present disclosure may include an apparatus. The apparatus may include a first delay line circuit including a first plurality of combinatorial logic circuits arranged sequentially. The first plurality of combinatorial logic circuits may include a first combinatorial logic circuit and a second combinatorial logic circuit. Each of the first and the second combinatorial logic circuits may have a plurality of inputs and a plurality of outputs.

The apparatus may include a second delay line circuit including a second plurality of combinatorial logic circuits arranged sequentially. The second plurality of combinatorial logic circuits may include a third combinatorial logic circuit and a fourth combinatorial logic circuit. Each of the third and the fourth combinatorial logic circuits may have a plurality of inputs and a plurality of outputs.

The apparatus may also include a pulse generation circuit to output a first generated pulse to a first input of the first combinatorial logic circuit and a second generated pulse to the third combinatorial logic circuit.

The apparatus may further include a capture circuit to capture a binary state of at least one of the plurality of outputs of the first, the second, the third, and the fourth combinatorial logic circuits. Each of the first, the second, the third, and the fourth combinatorial logic circuits may have a logic propagation path from a first input of the plurality of inputs to a first output of the plurality of outputs. The first input of the plurality of inputs may be to receive an input pulse and the first output of the plurality of outputs to output an output pulse. The logic propagation path may have a logic propagation delay between the input pulse and the output pulse. The logic propagation delay may be determined by a logic value applied to a second of the plurality of inputs. In the first delay line circuit, the first output of the first combinatorial logic circuit may be communicatively coupled to a first input of the second combinatorial logic circuit to propagate the first generated pulse through the first delay line circuit. In the second delay line circuit, the first output of the third combinatorial logic circuit may be communicatively coupled to a first input of the fourth combinatorial logic circuit to propagate the second generated pulse through the second delay line circuit.

In combination with any of the above examples, the plurality of combinatorial logic circuits may be a plurality of logic look up tables. At least one logic look up table of the plurality of logic look up tables may be a programmable logic function in a programmable fabric of a field programmable gate array. The plurality of inputs may be inputs of the plurality of logic look up tables. The plurality of outputs may be outputs of the plurality of logic look up tables.

In combination with any of the above examples, the plurality of combinatorial logic circuits may have a bypass control input to accept the input pulse at a bypass input. The pulse generation circuit may be to output the first generated pulse to the bypass input of one or more of the plurality of combinatorial logic circuits to bypass one or more combinatorial logic circuits in the first delay line circuit.

In combination with any of the above examples, the apparatus may include a control circuit. The control circuit may be to trigger, at a first time interval, a launch of the first generated pulse and a launch of the second generated pulse. The control circuit may also be to trigger, at a second time interval, a capture of the binary state of at least one of the plurality of outputs of the first, the second, the third, and the fourth combinatorial logic circuits. The apparatus may also include a data processing circuit. The data processing circuit may be to store the captures of the binary state of at least one of the plurality of outputs of the first, the second, the third, and the fourth combinatorial logic circuits. The data processing circuit may be to generate a time series of a plurality of aggregate propagation delays. A launch of the first generated pulse may be triggered by a first clock signal and a capture of the binary state of at least one of the plurality of outputs of the first and the second combinatorial logic circuits may be triggered by a second clock signal.

In combination with any of the above examples, the programmable fabric in the field programmable gate array may be to perform a function programmed by a user. The programmable fabric may be to draw an electrical current from a power delivery network of the field programmable gate array. The power delivery network may supply power to the first delay line circuit and the second delay line circuit. The aggregate propagation delay may indicate fluctuations in a voltage supplied by the power delivery network.

Alone or in combination with any of the above examples, examples of the present disclosure may include a method. The method may include sequentially arranging a plurality of combinatorial logic circuits in a delay line circuit. The plurality of combinatorial logic circuits may include a first combinatorial logic circuit and a second combinatorial logic circuit. Each of the first and the second combinatorial logic circuits may be a logic look up table in a programmable fabric of a field programmable gate array and may have a plurality of inputs to the logic look up table and a plurality of outputs of the logic look up table.

The method may also include providing a pulse generation circuit to, after being triggered by a first clock signal, output a generated pulse to a first input of the first combinatorial logic circuit.

The method may further include providing a capture circuit to, after being triggered by a second clock signal, record a binary state of at least one of the plurality of outputs of each of the first and the second combinatorial logic circuits.

The method may also include providing a control circuit. The control circuit may be to trigger, at a first time interval, a launch of the generated pulse. The control circuit may also be to trigger, at a second time intervals a capture of the binary state of at least one of the plurality of outputs of the first and the second combinatorial logic circuits.

The method may include providing a data processing and storage circuit. The data processing and storage circuit may be to store the captures of the binary state of at least one of the plurality of outputs of the first and the second combinatorial logic circuits. The data processing and storage circuit may be to generate a time series of a plurality of aggregate propagation delays. Each of the first and the second combinatorial logic circuits may have a logic propagation path from a first input of the plurality of inputs to a first output of the plurality of outputs. The first input of the plurality of inputs may be to receive an input pulse and an output of the plurality of outputs to output an output pulse. The logic propagation path may have a logic propagation delay between the input pulse and the output pulse. The logic propagation delay may be determined by a logic value applied to a second input of the plurality of inputs. The first output of the first combinatorial logic circuit may be communicatively coupled to a first input of the second combinatorial logic circuit to propagate the generated pulse through the delay line circuit.

### BRIEF DESCRIPTION OF THE DRAWINGS

The figures illustrate examples of systems and methods for the identification of system jitter in a circuit, such as an Application Specific Integrated Circuit (ASIC) or Field Programmable Gate Array (FPGA).

FIG. 1 is a block diagram of a time to digital conversion (TDC) circuit, according to examples of the present disclosure;

FIG. 2 is an illustration of a time to digital conversion (TDC) circuit including inputs from a trim circuit, according to examples of the present disclosure;

FIGS. 3A and 3B are illustrations of a time to digital conversion (TDC) circuit, according to examples of the present disclosure;

FIGS. 4A and 4B are illustrations of a time to digital conversion (TDC) circuit, according to examples of the present disclosure;

FIG. 5 illustrates a method performed for calculating a propagation delay through a TDC circuit, according to examples of the present disclosure; and

FIGS. 6A, 6B, 6C, and 6D illustrate input and output paths through a combinatorial logic circuit in an FPGA, according to examples of the present disclosure.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect of the invention, systems and methods for the identification of system jitter in a circuit, such as an Application Specific Integrated Circuit (ASIC) or Field Programmable Gate Array (FPGA) are provided. The disclosed systems and methods may provide for the identification of Total System Jitter (TSJ) in an ASIC and more specifically an FPGA, that is due to noise on the Power Delivery Network (PDN) inside the ASIC. The disclosed systems and methods may use a Time to Digital Conversion (TDC) circuit that a user may insert in various locations of the fabric portion of a FPGA to assist in identifying and mitigating excessive PDN. By reducing PDN, a user may increase the complexity and processing capabilities of the FPGA and may operate the programmed function at lower system cost.

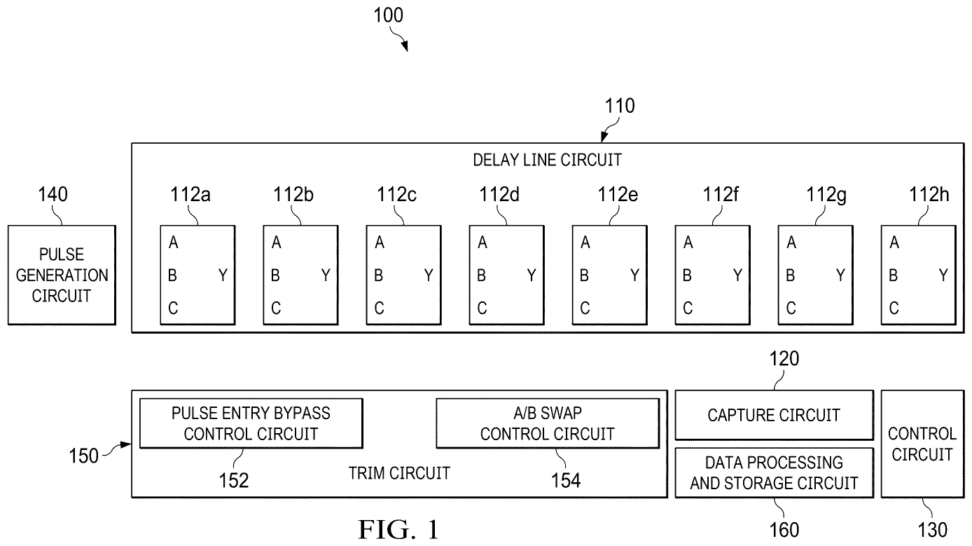

FIG. 1 is a block diagram of a time to digital conversion (TDC) circuit, according to examples of the present disclosure. TDC circuit 100 may include delay line circuit 110, data capture circuit 120, control circuit 130, pulse generation circuit 140, trim circuit 150, and data processing and storage circuit 160. TDC circuit 100 may be used to measure the temporal propagation depth of a signal, such as a digital pulse, through a circuit, and to convert the propagation depth to a digital number. In contrast to an analog-to-digital converter (ADC) that produces a digital number representing an analog value such as a voltage or a current relative to a reference, TDC circuit 100 may produce a digital number that may represent a delay. TDC circuit 100 may achieve a high delay resolution, and thus an effective delay increment that is less than, and generally a fraction of, the delay increment within a cascade of combinatorial logic circuits 112 of delay line circuit 110.

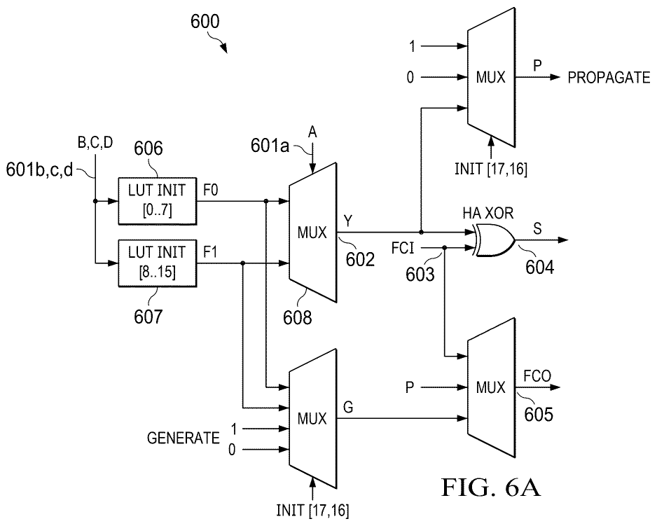

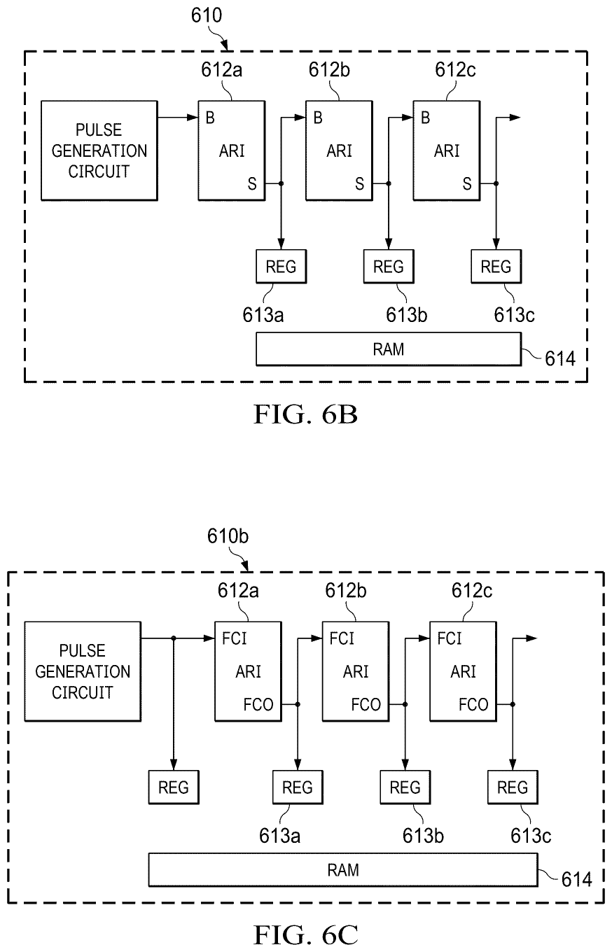

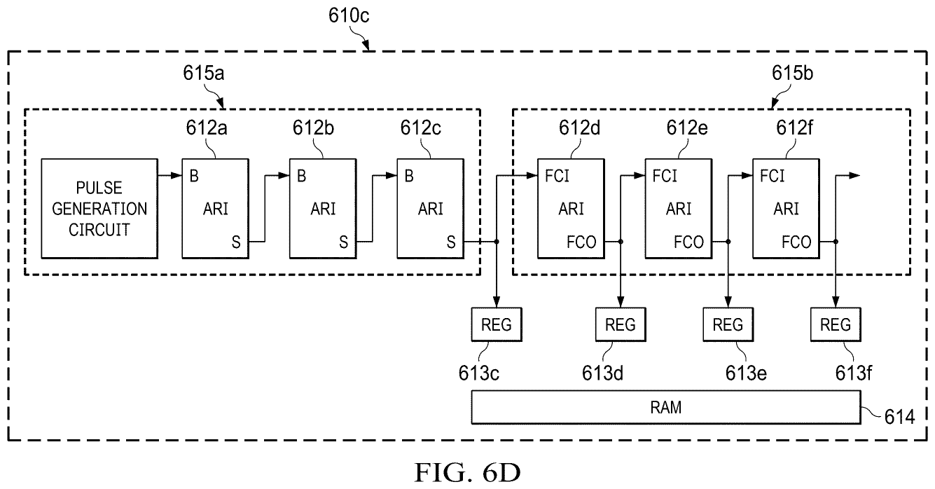

TDC circuit 100 may be implemented by all-digital circuit elements, and a user may design TDC circuit 100 using the digital circuit resources available in the programmable fabric of an FPGA, using the design flow provided by the design tools of the vendor of the FPGA. For example, TDC circuit 100 may be implemented in the fabric portion of an FPGA using typical fabric resources such as look-up tables, sequential logic elements and embedded RAM. The FPGA implementation of a TDC circuit is described in more detail with respect to FIG. 6, below.

During operation of an FPGA, the FPGA may draw an electrical current from a PDN. The supply voltage may contain noise and fluctuations that depend on various design decisions by the user such as the choice of clock sources, the clock frequencies, the overall resource count of the design, and any sub-system duty-cycling within the design. Supply fluctuations may be caused in part by current drawn by the circuits inside the FPGA that generate and process the various digital logic signals and clock signals as programmed by the user. The fluctuations may subject the logic and clocking signal to deterministic timing jitter and may effect the propagation delay through the FPGA (including TDC circuit 100). FPGA vendor tools may be used to program the device from the user's design files that define the intended logic function, the clocking scheme, and operating voltage. During various FPGA design stages, the PDN and clock jitter may be estimated and considered based on the programmed clock frequencies, the type of clock sources used, the desired logic functions, and the resource utilization of the design.

Another reason to add margin to the TSJ is the effect of circuit duty-cycling. When a circuit that is programmed on an FPGA is active, it draws more current than when it is inactive. The activity may, for instance, be controlled by internal enable signals, by freezing input signals entering sub-circuits, or by clock gating. Moreover, the activity may vary depending on different stages of processing. When a circuit is inactive, the ensuing low current draw is due to low leakage currents and current draw in its active clock tree. When the circuit is active, the current draw may be dominated by switching activity in the engaged logic circuits. During the active phase, the current is higher than during the inactive phase, and it is a task of the power supply system to regulate and stabilize the supply voltage under varying current loads. This may be accomplished by a closed loop regulator that senses the voltage and current at the FPGA supply terminals and regulates the supplied voltage, aided by decoupling capacitors. However, due to the impedances within the PDN of the FPGA, and the impedances of the bond wires and other interconnects between the silicon die of the FPGA and supply traces of the printed circuit board (PCB) it resides on, the fluctuations observed by the PSS at the PDN of the PCB outside the FPGA will not equal the fluctuations present on the PDN of the FPGA itself. This mismatch is most notable around the resonance frequency of the combined PDN formed by the die PDN, the PCB PDN and the pin and bond wire impedances. In addition to the combined PDN resonance there may also be other resonance frequencies due to interaction of capacitances and inductances on the die and, separately, due to capacitances and inductances on the PCB. Additionally, the location of the duty-cycling circuits on the FPGA chip may effect the TSJ and its effect on the integrity of clock generators and buffers, device input and output drivers, long routings, any subsystems such as a CPU, DDR controllers and peripheral SERDES systems in the FPGA.

The effects of excessive PDN noise, when it occurs beyond the applied margins, may be manifested by transient processing errors. Under some user operating conditions, the digital circuits of the FPGA may operate error free, and under other operating conditions there may be persistent logic errors, or worse, spurious logic errors, that may be difficult to root-cause diagnose. Moreover, it may be possible that PDN induced by one circuit, such as a soft-core processor that is duty cycling, may have an effect on a different circuit with critical timing jitter limits, such as DDR I/O ports.

It may therefore be beneficial to aid the user in isolating the duty cycling effects as a possible cause of logic errors using TDC circuit 100. The user may then re-architect portions of the design so that duty-cycling at resonance frequencies is less prevalent, avoiding elevated TSJ margins with costly effects. With the FPGA in operation, the user can determine when problematic duty cycling occurs, and correlate that with logic error events.

Delay line circuit 110 may be a cascade of combinatorial logic circuits 112a through 112h arranged sequentially. Combinatorial logic circuits 112a through 112h may be any suitable logic element such as, but not limited to, logic inverters or buffers, or a carry chain circuit in a carry-ripple-adder or a carry ripple function embedded in a digital multiplier circuit. In some examples, delay line circuit 110 may be a cascade of combinatorial logic circuits 112 which, in an FPGA, may be formed by cascading several look up tables. Delay line circuit 110 may receive power from the PDN that powers the FPGA.

The path through the look up tables may act as delay elements for delay line circuit 110. Specifically, a given look up table may contribute incrementally to the total delay of delay line circuit 110 and different logic functions programmed in a given look up table may have a different propagation time. For example, some input-to-output paths of a given look up table may traverse more internal transistors than others, and result in different input-to-output propagation times. As another example, a logic function such as an inversion or buffering may be achieved in more than one way in a given look up table and the different ways of performing the logic function (e.g., using different inputs and outputs) may result in different propagation delays. In some examples, the look up tables of combinatorial logic circuits 112 may be programmed to minimize the delay increment of TDC circuit 100.

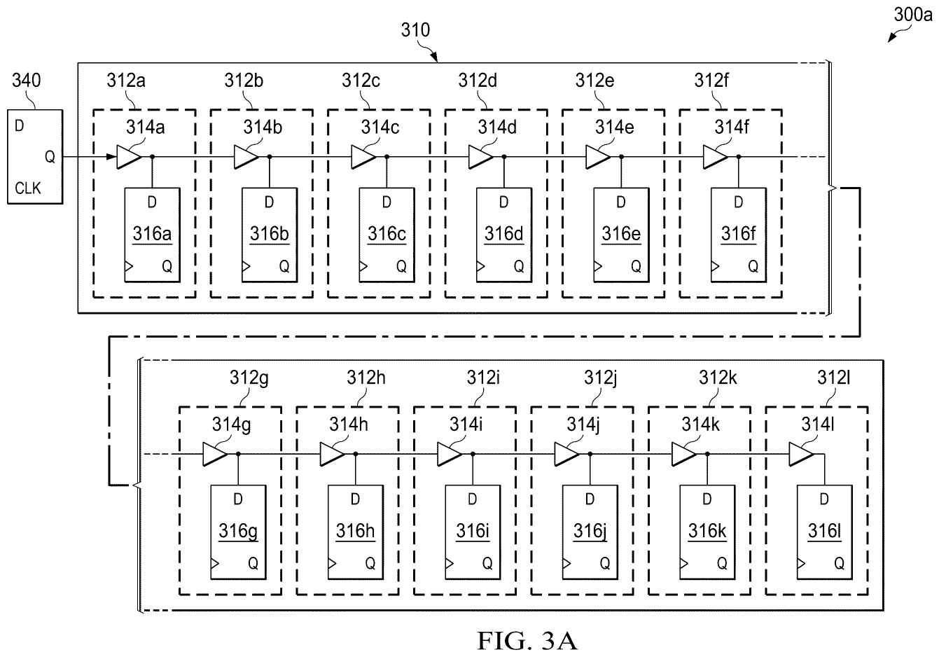

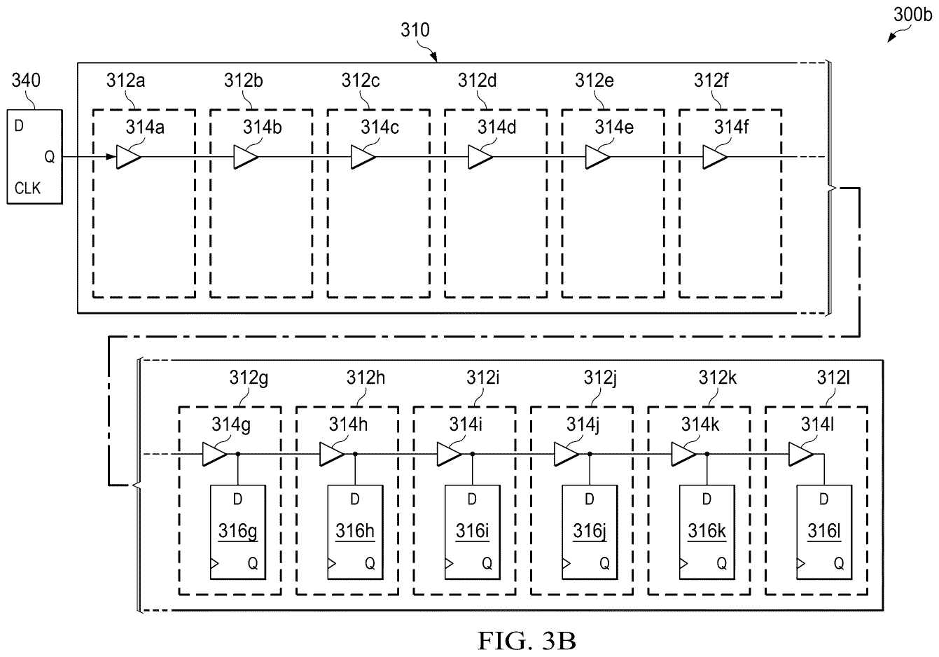

As shown in more detail in FIG. 3A, in some examples, combinatorial logic circuits 112 may be wired to sequential logic elements (e.g., flip-flops or registers) that are fed by intermediate signals occurring between the cascaded look up tables, and these sequential logic elements may be co-located with the look up tables in the fabric in so called logic clusters, forming a given combinatorial logic circuit 112. While delay line circuit 110 is shown in FIG. 1 as including eight combinatorial logic circuits 112a through 112h, delay line circuit 110 may include more or fewer combinatorial logic circuits 112. The length of delay line circuit 110 may be determined by the range of the supply voltage measurement and the super-imposed PDN extremes under investigation. A longer delay line may capture a longer range of pulse propagations depths and may measure a larger range of the supply voltage.

A given combinatorial logic circuit 112 may have a plurality of inputs (labeled A, B, and C in FIG. 1) and a plurality of outputs (labeled Y in FIG. 1) and a logic propagation path from a first of the plurality of inputs to a first of the plurality of outputs. The plurality of inputs and plurality of outputs of a given combinatorial logic circuit is illustrated in more detail with respect to FIG. 6, below. The first of the plurality of inputs may accept an input pulse and the first of the plurality of outputs may output an output pulse. The logic propagation path may have a logic propagation delay that may determine a pulse delay between the input pulse and the output pulse. The logic propagation delay may be determined by a logic value applied to a second of the plurality of inputs. As described below, the logic value may be provided by trim circuit 150. The first of the plurality of outputs of a first combinatorial logic circuit 112 may be electrically coupled to a first of the plurality of inputs of a second combinatorial logic circuit 112 to form the sequential arrangement of delay line circuit 110. The sequential arrangement may allow propagation of a pulse through delay line circuit 110.

Using combinatorial logic circuits 112 of delay line circuit 110, it may be possible to quantify the propagation time of a digital signal. For the purpose of measuring PDN noise, the propagation time (also referred to as the propagation delay) through combinatorial logic circuits 112 may depend on the voltage supplied to TDC circuit 100. A generated pulse may be output by pulse generation circuit 140 to a first input of a first of the combinatorial logic circuits 112 of delay line circuit 110. Thus, the noise and fluctuations of the supply voltage may be determined and measured by delay fluctuations through combinatorial logic circuits 112. Specifically, combinatorial logic circuits 112 may respond to a generated pulse (provided by pulse generation circuit 140), and at the active clock edge, capture circuit 120 may capture the binary states of each of the combinatorial logic circuits 112.

Capture circuit 120 may record the binary state of at least one of the plurality of outputs of each combinatorial logic circuit 112 in delay line circuit 110. Capture circuit 120 may be Finite State-Machine circuitry (FSM) programmed in an FPGA (e.g., a RAM unit embedded in the FPGA). In some examples, capture circuit 120 may perform a single capture upon a trigger. Alternatively, or additionally, capture circuit 120 may perform a sequence of captures by sampling the delay line at a specified sampling frequency. The duration and rate of the capture sequence may be adjusted depending on the nature of the PDN noise under investigation.

For example, the capture may be based on storage available in data processing and storage circuit 160. Specifically, the selection of rate of the capture, which affects the capture time resolution (also known as the time step or the time increment), and the duration of the capture may be selected to not exceed the available storage. To process the capture as a time series, multiple cycles of an anticipated dominant resonant oscillation of the PDN may be captured. The rate of capture may be calculated by dividing the capture duration by the number of RAM entries. For example, when a resonance of 1 megahertz (MHz) is under investigation, the duration of the capture may be 5 microseconds (μs). With a RAM depth of 2048 entries, the rate of the capture may have a maximum of 2048/5 us which equals approximately 410 MHz. The capture rate may also be based on the maximum pulse rate that can be achieved by the clocking circuit in the fabric of an FPGA. Moreover, the response of the PDN to several consecutive duty cycling events of a load circuit programmed by the user onto the FPGA may be captured. For this purpose, the TDC circuit may be configured for a longer capture duration to cover multiple duty cycle events, each duty cycle event lasting a few resonant cycles of the PDN. For example, a capture rate of 10 MHz and a RAM depth of 2048 entries provide a capture duration of approximately 205 μs. If the “on” and “off” phases of the load circuit are programmed to last 20 μs, the capture may cover 10 on/off cycling events.

Capture circuit 120 may capture an aggregate state of combinatorial logic circuits 112 by capturing the binary state of at least one of the plurality of outputs of each combinatorial logic circuit 112. Capture circuit 120 may calculate, using the aggregate state of combinatorial logic circuits 112, an aggregate propagation delay through delay line circuit 110.

The frequency at which pulses are launched from pulse generation circuit 140 to delay line circuit 110 may be limited by the time required for a pulse to traverse delay line circuit 110. Thus, while a longer delay line circuit 110 may be used to measure a large voltage range, the length of delay line circuit 110 may limit the pulse launch rate and the sampling frequency of the states of combinatorial logic circuits 112 captured by capture circuit 120. A sampling frequency that is multiple times higher than the launch rate of the pulses from pulse generation circuit 140 may be obtained while also measuring a large voltage range.

The delay increment may determine the temporal resolution of the capture of the logic states of combinatorial logic circuits 112. The total delay may be calculated by summing the delay increments of combinatorial logic circuits 112 in delay line circuit 110 to determine the temporal span of the capture. As explained above, the delay increment of a given combinatorial logic circuit 112 may be determined by the path through the look up table of the given combinatorial logic circuit 112. Additionally, the delay increment may be determined by the propagation delay through any additional combinatorial logic circuits and buffers, and logic multiplexers (muxes) that route logic signals from one combinatorial logic circuit 112 to the next combinatorial logic circuit 112.

Control and optimization of TDC circuit 100 may be adjusted by the user with interface functionality available in the FPGA. In some FPGAs, this may include tools and functions for accessing RAM to set trims (e.g., adjusting trim circuit 150), read captures (e.g., recorded by capture circuit 120), and process data (e.g., by data processing and storage circuit 160). In some examples, Joint Test Action Group (JTAG) and universal serial bus (USB) interfaces by the FPGA vendor may also be used for access. Thus, a user can improve a design and save significant time troubleshooting the design by adding TDC circuit 100. TDC circuit 100 may be added to or removed from the design by the user.

Trim circuit 150 may be set during the design phase of TDC circuit 100, during use of TDC circuit 100, or both. For example, a user may add TDC circuit 100 to a design and use trim circuit 150 to trim and re-trim the configuration of the delay to obtain the target measurement accuracy without redesigning TDC circuit 100 or iterating the placement and routing of TDC circuit 100.

When designing TDC circuit 100, a user may control the placement and routing of combinatorial logic circuits 112 of delay line circuit 110 to achieve fine temporal resolution and uniform increment amounts throughout delay line circuit 110. Such controlled placement may be available in the FPGA design tools provided by the FPGA vendor to minimize delays through and between combinatorial logic circuits 112. To achieve a given temporal resolution in TDC circuit 100, any logic routing delays between combinatorial logic circuits 112 may be minimized and combinatorial logic circuits 112 may be configured to perform a logic function with shortest propagation delay. The sub-total of propagation delays from the output of a given combinatorial logic circuit 112 to the output of the next combinatorial logic circuit 112 may be the minimum achievable delay increment in delay line circuit 110.

A uniform delay increment throughout delay line circuit 110 may be achieved by compensating for any unintentional variation of the delay increments due to placement and routing. Trim circuit 150 may compensate for the variation in the delay increments by trimming the delay through combinatorial logic circuits 112 of delay line circuit 110. For example, the logic propagation path through a given combinatorial logic circuit 112 may have a logic propagation delay that may determine a pulse delay between the input pulse and the output pulse. The logic propagation delay may be determined by a logic value applied to a second of the plurality of inputs. Trim circuit 150 may provide the logic value.

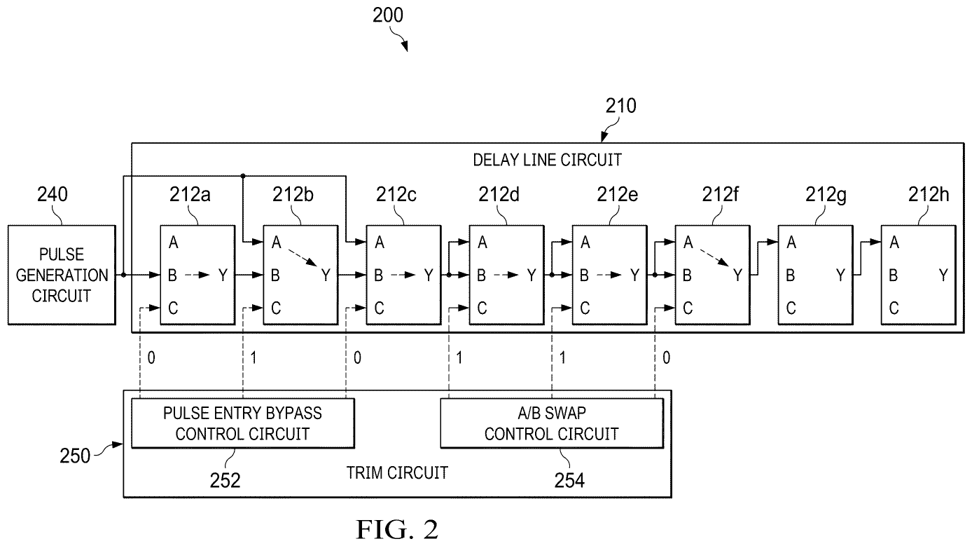

Since the selection of different input and output combinations for the logic function by a given combinatorial logic circuit 112 may yield different delays but a same logic function, trimming may be accomplished by configuring combinatorial logic circuits 112 to use different inputs and outputs. For example, pulse entry bypass control 152 may output a logic value to a given combinatorial logic circuit 112 to cause the given combinatorial logic circuit 112 to accept the generated pulse at a bypass input instead of the first of the plurality of inputs of the combinatorial logic circuit. When pulse generation circuit 140 outputs the generated pulse to the bypass input, one or more combinatorial logic circuits 112 may be bypassed. The bypass of one or more combinatorial logic circuits is illustrated in FIG. 2.

In logic simulations, after placement and routing of TDC circuit 100, it may be possible to include logic propagation delays of combinatorial logic circuits 112 and determine each individual delay increment throughout delay line circuit 110, by considering the logic propagation delay through a given combinatorial logic circuit 112 and additional delays from routing and buffering elements in the fabric between combinatorial logic circuits 112. In general, routing delays may be constant and minimal across combinatorial logic circuits 112 that are co-located within clusters of combinatorial logic circuits 112. Such clusters may be contained and tightly interconnected sub-areas within the fabric of an FPGA. It may be advantageous to control the placement of all or most of combinatorial logic circuits 112 within a cluster to ensure base-line uniformity. Any additional routing delays between clusters may be considered, and uniformity across clusters may be achieved by increasing the logic propagation delay through combinatorial logic circuits 112 within a cluster. With some FPGAs, it may be possible to implement combinatorial logic circuits 112 as macros. A given combinatorial logic circuit 112 may obtain different logic propagation delays by directly programming a simple logic function and selecting specific inputs and outputs of the given combinatorial logic circuit 112 using the logic value provided by trim circuit 150.

Trim circuit 150 may also trim TDC circuit 100 to obtain a measurement fidelity that is suitable for time series analysis of the PDN noise, in connection with duty cycling of a user design. Since TDC circuit 100 may use logic elements available for programming by the user, the required trim may be pre-determined by the user through post-layout simulations of TDC circuit 100. Trim circuit 150 may trim TDC circuit 100 by setting programmable functions of logic elements in the fabric, as already available to the user by the FPGA tool supplied by the FPGA vendor. Trim circuit 150 may be adjusted using interface functionality available in the FPGA (e.g., by accessing RAM to set trims and read captures or using JTAG and USB interfaces).

Using the information recorded by capture circuit 120, a user may determine the resonance frequencies of the PDN, and may determine whether their design has duty cycle rates that are at or near the resonance frequencies. In some examples where TDC circuit 100 is used for diagnostics during design of a circuit, once the user has adapted the design to the constraints imposed by PDN, TDC circuit 100 may be replaced by a simpler TDC circuit 100 for monitoring, or removed altogether, to free-up FPGA fabric resources for use by additional designs of the user.

In addition to determining resonance frequencies of the PDN, the fidelity of TDC circuit 100 may be used to thwart advanced tampering attempts. These attempts may be detected by measuring the transfer function of the PDN and detecting any changes to the transfer function due to the external application of sensing probes or removal of packaging by an attacker.

In some examples, TDC circuit 100 may be calibrated to determine the voltage inside the FPGA from the measured propagation delay. TDC circuit 100 may be calibrated by applying a constant voltage to the FPGA, disabling the switching of all other circuits so that no or little dynamic loading of the supply occurs, and determining the ensuing delay measured by TDC circuit 100. The calibration may be repeated by stepping the voltage range between the minimum and maximum operating voltage of TDC circuit 100, to obtain a voltage-delay calibration table. The calibration table may be used to determine absolute voltage levels and voltage time series from the delay captures, and the calibration table may also be used to compensate for any remaining non-uniformity of the delay increments.

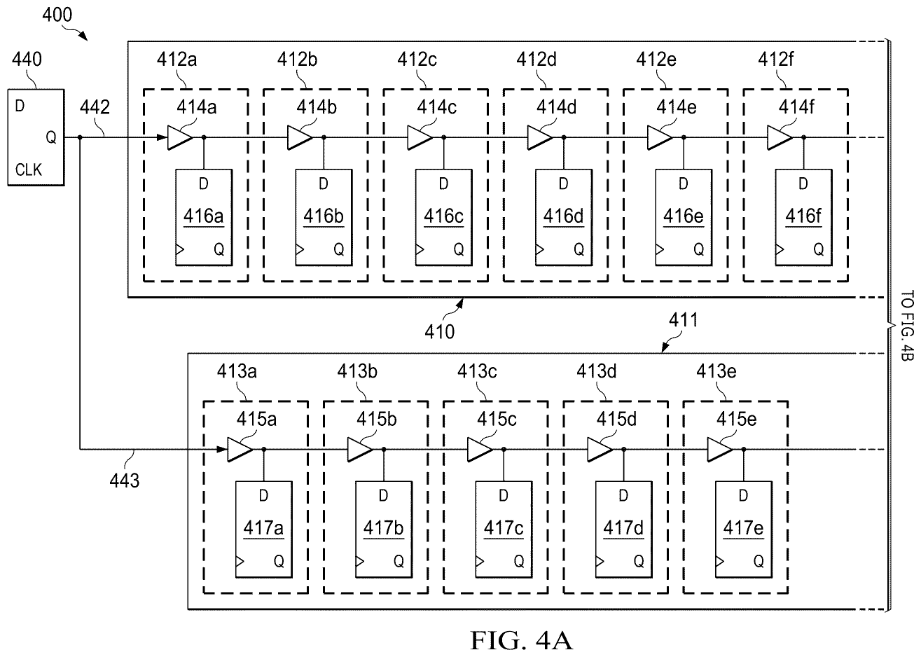

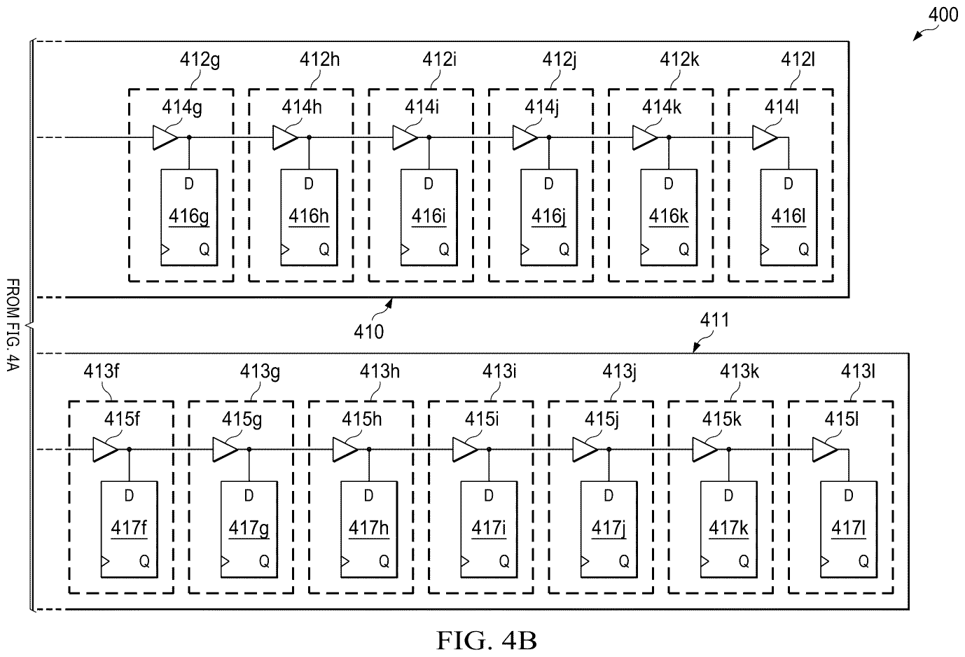

Some situations encountered by users may require a high fidelity TDC circuit 100, others may require a less fidelity TDC circuit 100. Some situations may use several TDC circuits 100 placed at different locations in the FPGA, and others may use a single TDC circuit 100. ASIC die area and FPGA logic resources may be limited, and it may be beneficial to only implement as many TDC circuits 100 as necessary for a TSJ/PDN noise measurement, where some diagnostic cases may use more and larger TDC circuits 100 and other cases may use fewer and smaller TDC circuits 100. Using configurable digital logic of the FPGA fabric provides flexibility to the user, and once the measurement and diagnostics are complete, and the user has adapted their design to the measured TSJ, TDC circuit 100 may be removed and the fabric logic that is freed up can be reclaimed and used by the user for other parts of the design. FIGS. 4A and 4B, below, describe a higher fidelity TDC circuit.

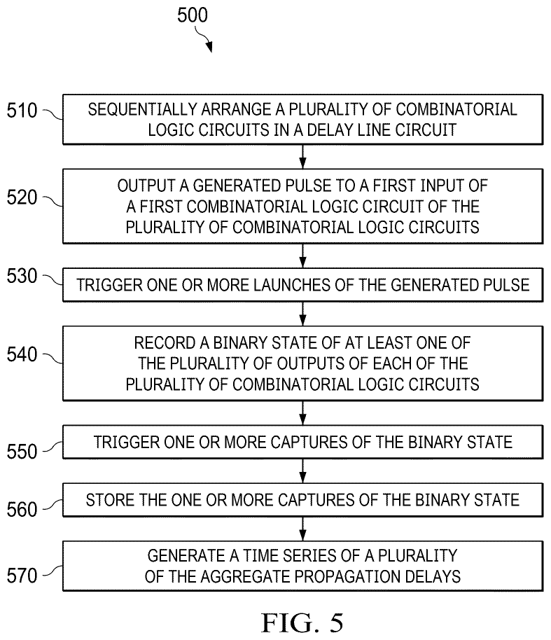

Control circuit 130 may be any suitable circuit for controlling the operation and functionality of TDC circuit 100, such as but not limited to, a central processing unit (CPU), a general purpose processor, a specific purpose processor, a microcontroller, a programmable logic controller (PLC), a digital signal processor (DSP), an application specific integrated circuit (ASIC), a field-programmable gate array (FPGA) or other programmable logic device, discrete gate or transistor logic, discrete hardware components, other programmable device, or any combination thereof. The operation of control circuit 130 is described in more detail below in reference to FIGS. 5 and 6.

Control circuit 130 may trigger, at a first plurality of time intervals, pulse generation circuit 140 to launch a generated pulse. Control circuit 130 may also trigger, at a second plurality of time intervals, capture circuit 120 to capture the binary state of at least one of the plurality of outputs of each of combinatorial logic circuits 112.

Data processing and storage circuit 160 may be any suitable circuit for controlling the operation and functionality of TDC circuit 100, such as but not limited to, a central processing unit (CPU), a general purpose processor, a specific purpose processor, a microcontroller, a programmable logic controller (PLC), a digital signal processor (DSP), an application specific integrated circuit (ASIC), a field-programmable gate array (FPGA) or other programmable logic device, discrete gate or transistor logic, discrete hardware components, other programmable device, or any combination thereof. Data processing and storage circuit 160 may store the one or more captures of the binary state of at least one of the plurality of outputs of each of combinatorial logic circuits 112 (from capture circuit 120) and generate a time series of the plurality of outputs. The time series may represent the propagation delay through delay line circuit 110 at a plurality of generated pulses. Data processing and storage circuit 160 may use the time series for calculating one or more resonant frequencies. Data processing and storage circuit 160 may also determine one or more extreme aggregate propagation delays from the time series (e.g., the highest (“maximum”) or lowest (“minimum”) delay that occurs in the time series). The highest extreme (e.g., the maximum delay) may be of interest and used to determine the maximum clocking frequency for a logic circuit operating under the investigated system jitter conditions. Data processing and storage circuit 160 may further relate a start time of a programmed function of the FPGA with a moment in the time series.

FIG. 2 is an illustration of a time to digital conversion (TDC) circuit including inputs from a trim circuit, according to examples of the present disclosure. TDC circuit 200 illustrates details of delay line circuit 210, which may be similar to delay line circuit 110 shown in FIG. 1. Delay line circuit 210 may be formed of combinatorial logic circuits 212a through 212h. TDC circuit 200 may also include a data capture circuit, a control circuit, and a data processing and storage circuit (not expressly shown) similar to data capture circuit 120, control circuit 130, and data processing and storage circuit 160 shown in FIG. 1.

Trim circuit 250 may include pulse entry bypass control circuit 252 and A/B swap control circuit 254. Pulse entry bypass control circuit 252 and A/B swap control circuit 254 may output logic inputs to one or more combinatorial logic circuits 212 to determine a logic propagation delay through combinatorial logic circuits 212 by bypassing one or more combinatorial logic circuits 212, determining the routing from an input of a given combinatorial logic circuit 212 to an output of the given combinatorial logic circuit 212.

In the example illustrated in FIG. 2, pulse entry bypass control circuit 252 may output a logic input of “0” to combinatorial logic circuits 212a and 212c and a logic input of “1” to combinatorial logic circuit 212b. The logic input of “1” may cause combinatorial logic circuit 212b to select the generated pulse from pulse generation circuit 240 at a bypass input (labeled A in FIG. 2) and output the pulse from the bypass input to the output (labeled Y in FIG. 2) of combinatorial logic circuit 212b. Additionally, A/B swap control circuit 254 may output a logic input of “1” to combinatorial logic circuits 212d and 212e and a logic input of “0” to combinatorial logic circuit 212f. The logic input of “1” may cause combinatorial logic circuits 212d and 212e to route the generated pulse from input B to the output while the logic input of “0” may cause combinatorial logic circuit 212f to route the generated pulse from input A to the output. In this way, the logic propagation delay through combinatorial logic circuits 212 may be defined by trim circuit 250 using the logic value.

In some examples, combinatorial logic circuits 212 may comprise logic look up tables. The bypass input may be a first input to the logic look up table and the bypass control input may be a second input of the logic look up table. A first of the plurality of outputs of the logic look up table may be an output of the logic look up table.

FIGS. 3A and 3B are illustrations of a time to digital conversion (TDC) circuit, according to examples of the present disclosure. TDC circuit 300 illustrates details of delay line circuit 310, which may be similar to delay line circuit 110 shown in FIG. 1. Delay line circuit 310 may be formed of logic circuits 312a through 312l. A given logic circuit 312 may be formed of combinatorial logic elements 314 with corresponding sequential logic elements 316 (e.g., look up tables with) that are fed by intermediate signals occurring between the cascaded look up tables 314. Corresponding sequential logic elements 316 for the capture circuit (e.g., capture circuit 120 shown in FIG. 1) may be co-located with the look up tables in the fabric in so called logic clusters. While delay line circuit 310 is shown in FIG. 3A as including twelve logic circuits 312a through 312l, delay line circuit 310 may include more or fewer logic circuits 312. Additionally, as shown in FIG. 3B, not all logic circuits 312 may include both a look up table 314 and a sequential logic element 316. For example, as shown in FIG. 3B, logic circuits 312a through 312f do not have sequential logic elements or may leave available sequential logic elements unused. The length of delay line circuit 310 may be determined by the range of the supply voltage measurement and the super-imposed PDN extremes under investigation. A longer delay line may capture a longer range of pulse propagations depths and may measure a larger range of the supply voltage.

To capture PDN noise, sequential logic elements 316 of delay line circuit 310 may be cleared and a digital pulse may be generated and launched by pulse generation circuit 340 at a first clock signal and applied to the input of lookup table 314a at the start of delay line circuit 310. At a second clock signal, a capture clock edge, the tap output value of a given lookup table 314 may be stored in the corresponding sequential logic element 316. Between the two clock signals, the pulse traverses delay line circuit 310, and the depth achieved by the pulse through delay line circuit 310 may be determined by the supply voltage applied to the elements of delay line circuit 310. A higher voltage may cause faster digital switching and faster propagation yielding more depth, and a lower voltage may cause slower digital switching and thus slower propagation. After capturing the state of sequential logic elements 316 and after the pulse completes its traversal through delay line circuit 310, sequential logic elements 316 may be cleared, and a next pulse may be launched by pulse generation circuit 340. In some examples, the first clock signal may have a phase offset relative to the second clock signal. The phase offset of the first clock signal and the second clock signal may be achieved by sourcing the clock signals from different phase offset outputs of a Phase Lock Loop (PLL).

After capturing the states of lookup tables 314 of delay line circuit 310 at the tap off points in the corresponding sequential logic elements 316, the depth may be determined by counting the number of sequential logic elements 316 that have an output value that is different form the cleared value when the pulse was launched by pulse generation circuit 340. This count may be stored in memory, such as capture circuit 120 shown in FIG. 1, from where it can be retrieved for further processing. The process of clearing, launching, and capturing can be repeated in rapid succession to collect a multitude of delay values corresponding to a multitude of subsequent samplings of the supply voltage. The further processing may involve retrieving the delay values from memory, graphing the delay over time, applying frequency analysis on the delay time series to determine power supply resonance frequencies, and to correlate notable deviations of the supply voltage with other salient events in the design of the user, such as duty cycling. Such further processing may be accomplished in the FPGA or in a computing device external to the FPGA.

For example, four pulses may be launched by pulse generation circuit 340. The binary states of sequential logic elements 316 may be as follows:

| | Binary output value of sequential logic element | | | | | | | | | | | |
|---|---|---|---|---|---|---|---|---|---|---|---|---|
| Pulse (V_{dd}) | 316a | 316b | 316c | 316d | 316e | 316f | 316g | 316h | 316i | 316j | 316k | 316l |
| 1.0 | 1 | 1 | 1 | 1 | 1 | 1 | 1 | 1 | 1 | 1 | 1 | 1 |
| 0.99 | 1 | 1 | 1 | 1 | 1 | 1 | 1 | 1 | 1 | 1 | 1 | 0 |
| 0.98 | 1 | 1 | 1 | 1 | 1 | 1 | 1 | 1 | 1 | 1 | 0 | 0 |
| 0.97 | 1 | 1 | 1 | 1 | 1 | 1 | 1 | 1 | 1 | 0 | 0 | 0 |

In this example, captures of the four pulse launches are shown. At V_{dd}=1.0 volts, the binary states of sequential logic elements 316 in delay line circuit 310 are all the same because the pulse is propagated through all sequential logic elements 316 of delay line circuit 310. As Vad decreases, the propagation of the pulse through sequential logic elements 316 of delay line circuit 310 decreases. The data shown in the table above may be the aggregate state of sequential logic elements 316 and may be used to generate a time series of the aggregate propagation delays through delay line circuit 310. The time series may be used to calculate one or more resonant frequencies of the time series, calculate one or more extreme aggregate propagation delays in the time series, relate a start time of the programmed function with a moment in the time series, or any combination thereof.

FIGS. 4A and 4B are illustrations of a time to digital conversion (TDC) circuit, according to examples of the present disclosure. TDC circuit 400 illustrates details of delay line circuits 410 and 411. Delay line circuits 410 and 411 may be similar to delay line circuit 110 shown in FIG. 1 or delay line circuit 310 shown in FIG. 3A. Delay line circuit 410 may be formed of logic circuits 412a through 412l. A given logic circuit 414 (which may comprise a programmable look up table) may be wired to sequential logic elements 416 (e.g., flip-flops or registers) that are fed by intermediate signals occurring between the combinatorial logic circuits 414, and these sequential logic elements may be co-located with the combinatorial logic circuits in the fabric in so called logic clusters, forming the given logic circuits 412a through 412l. Similarly, delay line circuit 411 may be formed of logic circuits 413a through 413l. A given logic circuit 413 may be formed of sequential logic elements 417 (e.g., flip-flops or registers) that are fed by intermediate signals occurring between the cascaded combinatorial logic circuits 415, and these sequential logic elements may be co-located with the look up tables in the fabric in so called logic clusters, forming the given logic circuit 413. While delay line circuits 410 and 411 are shown in FIGS. 4A and 4B as including twelve logic circuits 412a through 412l and 413a through 413l, respectively, delay line circuits 410 and 411 may include more or fewer logic circuits 412 and 413. The length of delay line circuits 410 and 411 may be determined by the range of the supply voltage measurement and the super-imposed PDN extremes under investigation. A longer delay line may capture a longer range of pulse propagations depths and may measure a larger range of the supply voltage.

As illustrated in FIGS. 4A and 4B, in some examples, delay line circuits 410 and 411 may be staggered to achieve higher resolution of the depth of the propagation of the pulse launched by pulse generation circuit 440. In concurrent delay line circuits 410 and 411, the launch of the pulse and the capture of the states of sequential logic elements 416 in delay line circuit 410 may be triggered by a clock signal that has a phase offset relative to the delay line circuit 411. Concurrent delay line circuits 410 and 411, each with offset pulse launch and state capture may allow the supply voltage to be captured at a rate that is a multiple of the pulse launch rate achievable in an example with a single delay line circuit.

Relative capture staggering among delay line circuits 410 and 411 may also be accomplished by trimming one or more combinatorial logic circuits 414 or 415 at the beginning of delay line circuit 410 or 411, respectively. For example, the pulse launched by pulse generation circuit 440 to delay line circuits 410 and 411 may be generally phase aligned, but the one or more combinatorial logic circuits 414 or 415 of delay line circuits 410 and 411 may be programmed differently between delay line circuits 410 and 411, such that the delay through the cascade of the one or more combinatorial logic circuits 414 or 415 may be different among delay line circuits 410 and 411. Thus, the pulses in delay line circuits 410 and 411 may have different delays entering the remainder of look-up tables 414 and 415. Furthermore, such initial delay adjustments may also be used to compensate for an unintended clock signal phase offset or unintended pulse launch offset into the start of delay line circuits 410 and 411. These unintended offsets may be caused by uncontrollable routing delays in the FPGA. Combining the compensation of unintended offsets with the application of an intended offset may achieve accurate relative phase alignment of pulses throughout delay line circuits 410 and 411. While one pulse generation circuit 440 is shown in FIGS. 4A and 4B, TDC circuit 500 may include multiple pulse generation circuits 440. An implementation including multiple pulse generation circuits 440 may allow the phase of the pulse launched by the pulse generation circuits 440 to be shifted between delay line circuit 410 and delay line circuit 411.

Relative staggering of delay line circuits 410 and 411 may also be accomplished by offsetting the launch time of the pulse from pulse generation circuit 440. Staggered pulse launches may be achieved by launching the pulses at active clock edges that are temporally relatively displaced at the inputs to delay line circuits 410 and 411. Alternatively or additionally, relative staggering of delay line circuits 410 and 411 may be achieved by offsetting the time the states of sequential logic elements 416 and 417 are captured by a capture circuit, such as capture circuit 120 shown in FIG. 1. The capture clock phase of delay line circuits 410 and 411 may be kept in a fixed phase relation to the launch clock edge of one of delay line circuits 410 or 411. Alternatively, the launch capture clock phases may be kept in a fixed phase relation to one of the capture clock phases, while employing phase displaced capture clocks across delay line circuits 410 and 411.

In some examples, the phase offset of the launch time of a pulse or the time of the capture of the states of sequential logic elements 416 and 417 may be achieved by sourcing the clock from different phase offset outputs of a Phase Lock Loop (PLL). Alternatively, a pulse may be routed through buffers and other logic in the pulse path, to induce a desired delay. By branching a pulse (e.g., into pulses 442 and 443) and routing each branched pulse 442 and 443 through different logic paths, pulses 442 and 443 may have different delays, and thus different synchronous but relatively phase displaced pulses are launched to concurrent delay line circuits 410 or 411.

In some examples, instead of employing concurrent delay line circuits 410 or 411, higher delay resolution may be achieved with a single delay line circuit, such as delay line circuit 110 shown in FIG. 1 or delay line circuit 310 shown in FIG. 3A. Under controlled duty cycle loading conditions, repeated captures may be made while also repeating the load duty cycling. The resolution of the depth of the delay may be achieved by a given capture of the states of the sequential logic elements (e.g., sequential logic elements 316 shown in FIG. 3A) employing a different, temporally relatively displaced pulse launch, and while keeping the load duty cycling the same during each pulse launch. Measurements obtained with different launch phases or different capture phases relative to the duty cycle events may be merged to form a combined measurement with an effectively higher delay increment resolution.

FIG. 5 illustrates a method performed for calculating a propagation delay through a TDC circuit, according to examples of the present disclosure. Method 500 may be implemented by a circuit using a central processing unit (CPU), a general purpose processor, a specific purpose processor, a microcontroller, a programmable logic controller (PLC), a digital signal processor (DSP), an application specific integrated circuit (ASIC), a field-programmable gate array (FPGA) or other programmable logic device, discrete gate or transistor logic, discrete hardware components, other programmable device, or any combination thereof designed to perform the functions disclosed herein, in combination with a processor, or any other system operable to implement method 500. Although examples have been described above, other variations and examples may be made from this disclosure without departing from the spirit and scope of these disclosed examples.

Method 500 may begin at block 510 where a plurality of combinatorial logic circuits may be sequentially arranged into a delay line circuit. Each combinatorial logic circuit may have a plurality of inputs and a plurality of outputs. In some examples, the combinatorial logic circuits may be logic look up tables in a programmable fabric of an FPGA. In this example, the plurality of inputs may be inputs to the logic look up table and the plurality of outputs are outputs of the logic look up table. Each combinatorial logic circuit may have a logic propagation path from a first of the plurality of inputs to a first of the plurality of outputs. The logic propagation path may have a logic propagation delay that may determine a pulse delay between a pulse being input to the combinatorial logic circuit and the pulse being output from the combinatorial logic circuit. The logic propagation delay may be determined based on a logic value applied to an input to the combinatorial logic circuit. The logic value may be applied by a trim circuit, such as trim circuit 150 shown in FIG. 1, and may be applied to a different input than the input that receives a pulse.

At block 520, a generated pulse may be output to a first input of the first combinatorial logic circuit in the plurality of combinatorial logic circuits in the delay line circuit (e.g., the generated pulse may be output to combinatorial logic circuit 112a shown in FIG. 1). In some examples, the generated pulse may be output after being triggered by a first clock signal. The generated pulse may be output by a pulse generation circuit, such as pulse generation circuit 140 shown in FIG. 1. The generated pulse may be propagated through the delay line circuit by being output from one of the plurality of outputs of one of the combinatorial logic circuits in the delay line circuit to one of the plurality of inputs of the next combinatorial logic circuit in the delay line circuit.

At block 530, one or more launches of the generated pulse may be triggered. The launches of the generated pulse may be triggered by a control circuit, such as control circuit 130 shown in FIG. 1. The launches may be triggered at a first plurality of time intervals.

At block 540, a binary state of at least one of the outputs of each of the combinatorial logic circuits in the delay line circuit may be recorded. The binary state may be recorded by a capture circuit, such as capture circuit 120 shown in FIG. 1. In some examples, the recording of the binary state may be triggered by a second clock signal.

At block 550, one or more captures of the binary state of at least one of the outputs of each of the combinatorial logic circuits in the delay line circuit may be triggered. The captures of the binary state may be triggered by a control circuit, such as control circuit 130 shown in FIG. 1. The captures may be triggered a second plurality of time intervals that may be different from the first plurality of time intervals at block 530.

At block 560, the captures of the binary state may be stored. The captures may be stored by a data processing and storage circuit, such as data processing and storage circuit 160 shown in FIG. 1.

At block 570, a time series of a plurality of the aggregate propagation delays may be generated. The time series may be generated by a data processing and storage circuit, such as data processing and storage circuit 160 shown in FIG. 1. The aggregate propagation delays may be determined based on the plurality of captures of the binary states of the combinatorial logic circuits in the delay line circuit (recorded at block 540 and stored at block 560.

Although FIG. 5 discloses a particular number of operations related to method 500, method 500 may be executed with greater or fewer operations than those depicted in FIG. 5. In addition, although FIG. 5 discloses a certain order of operations to be taken with respect to method 500, the operations comprising method 500 may be completed in any suitable order.

FIGS. 6A, 6B, 6C, and 6D illustrate input and output paths through a combinatorial logic circuit in an FPGA, according to examples of the present disclosure. FPGA 600 may implement a combinatorial logic circuit, such as combinatorial logic circuits 112 shown in FIG. 1. The combinatorial logic circuit may be combined with other combinatorial logic circuits in FPGA 600 to form a delay line circuit, such as delay line circuit 110 shown in FIG. 1. FPGA 600 may be any suitable FPGA. For example, FPGA 600 may be a PolarFire® FPGA sold by Microchip Technology Inc. The plurality of inputs and plurality of outputs of the combinatorial logic circuits may be implemented by “arithmetic 4-LUT” logic elements in sequential arrangements within Logic Clusters of the programmable fabric of the FPGA.

FPGA 600 may include arithmetic logic elements with ports B, C, and D 601b, 601c, and 601d, respectively, as a plurality of inputs to look-up tables 606 and 607. Look-up tables 606 and 607 may be 8-entry look-up tables. Port A 601a may be an input to multiplexer 608. The input may be used to select between look-up tables 606 and 607. Port Y 602 may be the output of multiplexer 608. FPGA 600 may have a plurality of outputs including output 604 and output 605. The propagation delay between ports B, C and D 601b, 601c, and 601d, respectively, may be determined by the choice between look up table 606 and 607 (from multiplexer 608) and the choice of input-to-output path starting at port B C or D, as programmed by contents of look-up-tables 606 and 607. For example, the delay line of TDC circuit 610 may be formed by a cascade of logic elements 612a, 612b, and 612c. Logic elements 612a, 612b, and 612c may be a fabric macro for arithmetic operations in FPGA 600, such as the ARII macro available for the PolarFire® FPGA sold by Microchip Technology Inc. The outputs of logic elements 612a, 612b, and 612c may be captured in registers 613a, 613b, 613c, respectively, and the contents of registers 613a, 613b, and 613c may be transferred to embedded RAM 614. Combinatorial logic circuit 612a, 612b, and 612c each illustrate an input-to-output path from port B 601b to output port S 604 shown in FIG. 6A.

FIG. 6C illustrates a second example logic path in FPGA 600 to form a delay line circuit of TDC 610b. The delay line circuit of TDC 610b may be formed by a cascade of logic elements 612a, 612b, and 612c. The outputs of logic elements 612a, 612b, and 612c may be captured in registers 613a, 613b, 613c, respectively, and the contents of registers 613a, 613b, and 613c may be transferred to embedded RAM 614. Combinatorial logic circuit 612a, 612b, and 612c each illustrate an input-to-output path from port 603 (which may be a fast carry input (FCI) port) to output port 605 (which may be a fast carry output (FCO) port) shown in FIG. 6A. In the example logic path of FIG. 6C, ports B, C and D 601b, 601c, and 601d may be bypassed.

FIG. 6D illustrates a third example logic path in FPGA 600 to form delay line circuit for TDC 610c. Delay line circuit of TDC 610c may include two portions 615a and 615b. Portion 615a may not include capture registers for logic elements 612a, 612b, and 612c while portion 615b includes capture registers 613c, 613d, 613e, and 613f, for logic elements 612d, 612e, and 612f, respectively. To increase the sensitivity of the aggregate delay through delay line circuit of TDC 610c to the supply voltage, a cascade of logic elements 612a, 612b, and 612c without capture registers, each with a long logic path from input B (e.g., 601b shown in FIG. 6a) to output S (e.g., output 604 shown in FIG. 6A), may be followed by a cascade of logic elements 612d, 612e, and 612f, each with a short logic path from input FCI (e.g., input 603 shown in FIG. 6A) to output FCO (e.g., output 605 shown in FIG. 6A). Users may use post-synthesis and post-placement and routing simulation to account for additional delay contributions from routing multiplexers and routing buffers in FPGA 600. In some examples of FPGA 600, there may be additional buffering delay between logic clusters in FPGA 600. To maintain substantially uniform delay increments within portion 615b, the routing of logic elements to logic elements within two adjacent clusters of logic elements may be constrained, and the logic elements may be placed such that the break between clusters falls at the transition between portion 615a and 615b.

Although examples have been described above, other variations and examples may be made from this disclosure without departing from the spirit and scope of these disclosed examples.

1. An apparatus, comprising:
a delay line circuit including a plurality of combinatorial logic circuits arranged sequentially, the plurality of combinatorial logic circuits including a first combinatorial logic circuit and a second combinatorial logic circuit, each of the first and the second combinatorial logic circuits having a plurality of inputs and a plurality of outputs;
a pulse generation circuit to output a generated pulse to a first input of the first combinatorial logic circuit of the delay line circuit; and
a capture circuit to capture a binary state of at least one of the plurality of outputs of at least one of the plurality of combinatorial logic circuits;
wherein:
each of the first and the second combinatorial logic circuits has a logic propagation path from a first input of the plurality of inputs to a first output of the plurality of outputs, the first input of the plurality of inputs to receive an input pulse and the first output of the plurality of outputs to output an output pulse;
the logic propagation path has a logic propagation delay between the input pulse and the output pulse, the logic propagation delay determined by a logic value applied to a second input of the plurality of inputs; and
the first output of the first combinatorial logic circuit is communicatively coupled to a first input of the second combinatorial logic circuit to propagate the generated pulse through the delay line circuit.

2. The apparatus of claim 1, wherein:
the plurality of combinatorial logic circuits include a plurality of logic look up tables;
the plurality of inputs are inputs of the plurality of logic look up tables; and
the plurality of outputs are outputs of the plurality of logic look up tables.

3. The apparatus of claim 2, wherein the logic look up table is a programmable logic function in a programmable fabric of a field programmable gate array.

4. The apparatus of claim 1, wherein:
the plurality of combinatorial logic circuits have a bypass control input to accept the input pulse at a bypass input; and
the pulse generation circuit is to output the generated pulse to the bypass input of one or more of the plurality of combinatorial logic circuits to bypass the one or more combinatorial logic circuits in the delay line circuit.

5. The apparatus of claim 1, wherein a launch of the generated pulse is triggered by a first clock signal and a capture of the binary state is triggered by a second clock signal.

6. The apparatus of claim 5, wherein the first clock signal has a phase offset relative to the second clock signal.

7. The apparatus of claim 4, wherein:
the plurality of combinatorial logic circuits include a plurality of logic look up tables;
the bypass input is a first input of each of the plurality of logic look up tables;
the bypass control input is a second input of each of the plurality of logic look up tables; and
the output is an output of each of the plurality of logic look up tables.

8. The apparatus of claim 1, wherein the capture circuit is to:
capture an aggregate state of the plurality of combinatorial logic circuits by capturing the binary state of at least one of the plurality of outputs of each of the first and the second combinatorial logic circuits; and
calculate from the aggregate state of the plurality of combinatorial logic circuits an aggregate propagation delay through the delay line circuit.

9. The apparatus of claim 5, comprising a control circuit to:
trigger, at a first time interval, a launch of the generated pulse; and
trigger, at a second time interval, a capture of the binary state of at least one of the plurality of outputs of the first and the second combinatorial logic circuits.

10. The apparatus of claim 8, comprising a data processing and storage circuit to:
store the captures of the binary states of at least one of the plurality of outputs of each of the first and the second combinatorial logic circuits; and
generate a time series of a plurality of aggregate propagation delays.

11. The apparatus of claim 10, wherein the data processing and storage circuit is to calculate one or more resonant frequencies based on the time series.

12. The apparatus of claim 10, wherein the data processing and storage circuit is to determine, based on the time series, a maximum aggregate propagation delay or a minimum aggregate propagation delay.

13. The apparatus of claim 10, comprising a programmable fabric in a field programmable gate array to perform a function programmed by a user,
wherein:
the programmable fabric is to draw an electrical current from a power delivery network of the field programmable gate array, the power delivery network to supply power to the delay line circuit; and
the aggregate propagation delay indicates fluctuations in a voltage supplied by the power delivery network.

14. The apparatus of claim 13, wherein the data processing and storage circuit is to relate a start time of the function with a time in the time series.

15. An apparatus, comprising:
a first delay line circuit including a first plurality of combinatorial logic circuits arranged sequentially, the first plurality of combinatorial logic circuits including a first combinatorial logic circuit and a second combinatorial logic circuit, each of the first and the second combinatorial logic circuits having a plurality of inputs and a plurality of outputs;
a second delay line circuit including a second plurality of combinatorial logic circuits arranged sequentially, the second plurality of combinatorial logic circuits including a third combinatorial logic circuit and a fourth combinatorial logic circuit, each of the third and the fourth combinatorial logic circuits having a plurality of inputs and a plurality of outputs;
a pulse generation circuit to output a first generated pulse to a first input of the first combinatorial logic circuit and a second generated pulse to the third combinatorial logic circuit; and
a capture circuit to capture a binary state of at least one of the plurality of outputs of the first, the second, the third, and the fourth combinatorial logic circuits;
wherein:
each of the first, the second, the third, and the fourth combinatorial logic circuits has a logic propagation path from a first input of the plurality of inputs to a first output of the plurality of outputs, the first input of the plurality of inputs to receive an input pulse and the first output of the plurality of outputs to output an output pulse;
the logic propagation path has a logic propagation delay between the input pulse and the output pulse, the logic propagation delay determined by a logic value applied to a second of the plurality of inputs;
in the first delay line circuit, the first output of the first combinatorial logic circuit is communicatively coupled to a first input of the second combinatorial logic circuit to propagate the first generated pulse through the first delay line circuit, and
in the second delay line circuit, the first output of the third combinatorial logic circuit is communicatively coupled to a first input of the fourth combinatorial logic circuit to propagate the second generated pulse through the second delay line circuit.

16. The apparatus of claim 15, wherein:
the plurality of combinatorial logic circuits are a plurality of logic look up tables, at least one logic look up table of the plurality of logic look up tables is a programmable logic function in a programmable fabric of a field programmable gate array;
the plurality of inputs are inputs of the plurality of logic look up tables; and
the plurality of outputs are outputs of the plurality of logic look up tables.

17. The apparatus of claim 16, wherein:
the plurality of combinatorial logic circuits have a bypass control input to accept the input pulse at a bypass input; and
the pulse generation circuit is to output the first generated pulse to the bypass input of one or more of the plurality of combinatorial logic circuits to bypass one or more combinatorial logic circuits in the first delay line circuit.

18. The apparatus of claim 16, comprising:
a control circuit to:
trigger, at a first time interval, a launch of the first generated pulse and a launch of the second generated pulse; and
trigger, at a second time interval, a capture of the binary state of at least one of the plurality of outputs of the first, the second, the third, and the fourth combinatorial logic circuits; and
a data processing circuit to:
store the captures of the binary state of at least one of the plurality of outputs of the first, the second, the third, and the fourth combinatorial logic circuits; and
generate a time series of a plurality of aggregate propagation delays;
wherein a launch of the first generated pulse is triggered by a first clock signal and a capture of the binary state of at least one of the plurality of outputs of the first and the second combinatorial logic circuits is triggered by a second clock signal.

19. The apparatus of claim 16, wherein:
the programmable fabric in the field programmable gate array is to perform a function programmed by a user;
the programmable fabric is to draw an electrical current from a power delivery network of the field programmable gate array, the power delivery network to supply power to the first delay line circuit and the second delay line circuit; and
the aggregate propagation delay indicates fluctuations in a voltage supplied by the power delivery network.

20. A method, comprising:
sequentially arranging a plurality of combinatorial logic circuits in a delay line circuit, the plurality of combinatorial logic circuits including a first combinatorial logic circuit and a second combinatorial logic circuit, each of the first and the second combinatorial logic circuits is a logic look up table in a programmable fabric of a field programmable gate array and has a plurality of inputs to the logic look up table and a plurality of outputs of the logic look up table;
providing a pulse generation circuit to, after being triggered by a first clock signal, output a generated pulse to a first input of the first combinatorial logic circuit;
providing a capture circuit to, after being triggered by a second clock signal, record a binary state of at least one of the plurality of outputs of each of the first and the second combinatorial logic circuits;
providing a control circuit to:
trigger, at a first time interval, a launch of the generated pulse, and
trigger, at a second time intervals a capture of the binary state of at least one of the plurality of outputs of the first and the second combinatorial logic circuits; and
providing a data processing and storage circuit to:
store the captures of the binary state of at least one of the plurality of outputs of the first and the second combinatorial logic circuits; and
generate a time series of a plurality of aggregate propagation delays;
wherein:
each of the first and the second combinatorial logic circuits has a logic propagation path from a first input of the plurality of inputs to a first output of the plurality of outputs, the first input of the plurality of inputs to receive an input pulse and an output of the plurality of outputs to output an output pulse;
the logic propagation path has a logic propagation delay between the input pulse and the output pulse, the logic propagation delay determined by a logic value applied to a second input of the plurality of inputs; and
the first output of the first combinatorial logic circuit is communicatively coupled to a first input of the second combinatorial logic circuit to propagate the generated pulse through the delay line circuit.
